(19) United States
(12) Patent Application Publication
(10) Pub. No.: US 2008/0214009 A1
(43) Pub. Date: Sep. 4, 2008

(54) Methods of Forming a Recess Structure and Methods of Manufacturing a Semiconductor Device Having a Recessed-Gate Structure

(75) Inventors: Chi-Hoon Lee, Gyeonggi-do (KR); Jong-Chul Park, Gyeonggi-do (KR); Tae-Woo Lee, Gyeonggi-do (KR); Tae-Woo Kang, Gyeonggi-do (KR); Jang-Bin Yim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/020,841

(22) Filed: Jan. 28, 2008

(30) Foreign Application Priority Data
Jan. 30, 2007 (KR) 2007-9505

(51) Int. Cl. H01L 21/311

(52) U.S. Cl. 438/696; 257/E21.249

(57) ABSTRACT

Methods of forming a recess structure having a gentle curvature are provided. Such methods include forming a hard mask on a substrate, forming a first preliminary recess on the substrate using the hard mask as an etching mask and forming a spacer on a sidewall of the first preliminary recess. Methods may include forming a second preliminary recess from the first preliminary recess using the spacer as an etching mask and forming the recess structure having an enlarged lower portion from the second preliminary recess using the spacer as an etching mask.

### CROSS-REFERENCE TO RELATED APPLICATION

This application claims priority under 35 USC §119 to Korean Patent Application No. 10-2007-0009505, filed on Jan. 30, 2007 in the Korean Intellectual Property Office (ICIPO), the contents of which are herein incorporated by reference in their entirety.

### BACKGROUND OF THE INVENTION

The present invention relates to semiconductor methods and, more particularly, to forming semiconductor structural features.

As degrees of integration of semiconductor devices have increased, the dimensions of elements and widths of wirings have been reduced in the semiconductor devices. Accordingly, the dimensions of the semiconductor devices including the elements may have also been reduced. When a semiconductor device includes elements of minute size, an area for a gate structure may considerably decrease. For example, various methods have been developed to increase a gate channel length when the gate structure is formed in the reduced area. For example, a method of Conning a recessed gate having a lower portion buried in a semiconductor substrate has been developed to provide a proper channel length of a semiconductor device such as a spherical-shaped recess channel array transistor (S-RCAT).

In methods of forming a conventional S-RCAT, however, a sharp portion (that is, a cusp) may be generated between an upper portion and a lower portion of a recess structure formed on the semiconductor substrate. The sharp portion may cause damage to a gate insulation layer and/or a gate electrode formed in the recess structure.

Reference is now made to FIG. 1, which is an electron microscope image showing a cross-section of the conventional recess structure formed on the semiconductor substrate. As shown in FIG. 1, when the conventional recess structure is formed on a semiconductor substrate, a sharp portion (cusp) having a sharp angle of about 103° may be generated between the upper portion and the lower portion of the recess structure. When the gate insulation layer is formed on an inner portion of the recess structure having the sharp portion, the gate insulation layer may not be formed on the sharp portion of the recess structure. That is, the gate insulation layer may not be uniformly formed on a surface of the recess structure. If the gate insulation layer has an irregular thickness, electrical characteristics of the semiconductor device including the gate insulation layer may degrade. Further, when the gate structure is formed in the recess structure having the sharp portion, the gate structure may not sufficiently fill up the recess structure. In this regard, voids may be frequently generated at a lower portion of the gate structure. As a result, the semiconductor device including such a gate insulation layer and/or gate structure may have poor electrical characteristics and reliability.

### SUMMARY OF THE INVENTION

Some embodiments of the present invention provide methods of forming a recess structure having a gentle curvature between an upper portion and a Tower portion. Some embodiments of methods of forming a recess structure include forming a hard mask on a substrate, forming a first preliminary recess on the substrate using the hard mask as an etching mask and forming a spacer on a sidewall of the first preliminary recess. Methods may include forming a second preliminary recess from the first preliminary recess using the spacer as an etching mask and forming the recess structure having an enlarged lower portion from the second preliminary recess using the spacer as an etching mask.

In some embodiments, methods may include forming a pad oxide layer pattern between the substrate and the hard mask. In some embodiments, forming the pad oxide layer pattern and forming the hard mask may include forming a pad oxide layer on the substrate, forming a hard mask layer on the pad oxide layer and partially etching the hard mask layer and the pad oxide layer. In some embodiments, forming the pad oxide layer pattern may include using oxide and forming the hard mask includes using nitride and/or oxynitride.

Some embodiments may provide that the first preliminary recess includes a first width and a first depth and the second preliminary recess includes a second width that is substantially the same as the first width and a second depth that is substantially greater than the first depth.

In some embodiments, forming the first preliminary recess may include performing an anisotropic etching process. Some embodiments may provide that forming the second preliminary recess includes performing an anisotropic etching process. In some embodiments, forming the recess structure may include performing an isotropic etching process. Some embodiments may provide that forming the second preliminary recess includes etching until a lower portion of the spacer is exposed.

In some embodiments, an inclination angle between an upper portion and the lower portion of the recess structure may be greater than about 130°. In some embodiments, the lower portion of the recess structure may include a circular or elliptical shape. Some embodiments may include cleaning the recess structure. Yet further embodiments may include removing the hard mask while forming the spacer.

Some embodiments of the present invention may include methods of manufacturing a semiconductor device. Embodiments of such methods may include forming an isolation layer on a substrate to define an active region, forming a hard mask on the substrate, forming a first preliminary recess in the active region of the substrate using the hard mask as an etching mask and forming a spacer on a sidewall of the first preliminary recess. Some embodiments may include forming a second preliminary recess from the first preliminary recess using the spacer as an etching mask, forming a recess structure having an enlarged lower portion from the second preliminary recess using the spacer as an etching mask, forming a gate insulation layer on an inner portion of the recess structure and the substrate and forming a recessed-gate structure having a lower portion filling the recess structure on the gate insulation layer.

In some embodiments, forming the recess structure may include etching the second preliminary recess until a lower portion of the spacer is exposed. In some embodiments, a lower portion of the recess structure may include an elliptical or a circular shape and an inclination angle between an upper portion and the lower portion of the recess structure may be greater than about 130°.

Some embodiments may include removing the hard mask while forming the spacer. In some embodiments, the gate insulation layer may include silicon oxide or a metal oxide having a high dielectric constant. In some embodiments, forming the recessed-gate structure may further include forming a first conductive layer pattern that is configured to fill the recess structure and protrude from the substrate and forming a second conductive layer pattern on the first conductive layer pattern. Some embodiments may include cleaning the substrate that includes the recess structure prior to forming the gate insulation layer.

### BRIEF DESCRIPTION OF THE DRAWINGS

FIG. 1 is an electron microscope image showing a section of a semiconductor substrate having a conventional recess structure formed thereon.

FIGS. 2 to 8 are cross-sectional views illustrating operations in methods of manufacturing a semiconductor device having a recess structure according to some embodiments of the present invention.

FIG. 9 is an electron microscope image showing a section of a semiconductor substrate having a recess structure according to some embodiments of the present invention.

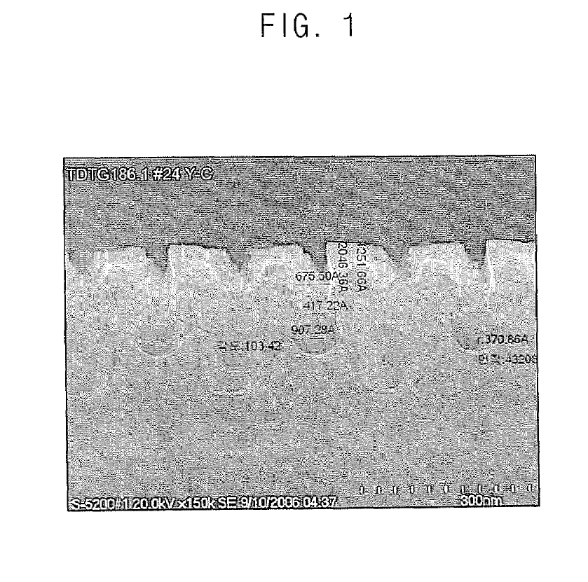

### DESCRIPTION OF THE EMBODIMENTS

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present invention. In addition, as used herein, the singular forms “a”, “an” and “the” are intended to include the plural forms as well, unless the context clearly indicates otherwise. It also will be understood that, as used herein, the term “comprising” or “comprises” is open-ended, and includes one or more stated elements, steps and/or functions without precluding one or more unstated elements, steps and/or functions. The term “and/or” includes any and all combinations of one or more of the associated listed items.

It will also be understood that when an element is referred to as being “connected” to another element, it can be directly connected to the other element or intervening elements may be present. In contrast, when an element is referred to as being “directly connected” to another element, there are no intervening elements present. It will also be understood that the sizes and relative orientations of the illustrated elements are not shown to scale, and in some instances they have been exaggerated for purposes of explanation. Like numbers refer to like elements throughout.

In the figures, the dimensions of structural components, including layers and regions among others, are not to scale and may be exaggerated to provide clarity of the concepts herein. It will also be understood that when a layer (or layer) is referred to as being ‘on’ another layer or substrate, it can be directly on the other layer or substrate, or can be separated by intervening layers. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Some embodiments are described herein with reference to cross-section illustrations that are schematic illustrations. Variations from the shapes of the illustrations as a result, for example, of manufacturing techniques and/or tolerances, may be expected. For example, an implanted region illustrated as a rectangle may, typically, include rounded and/or curved features and/or a gradient of implant concentration at its edges rather than a binary change from implanted to none implanted region. Likewise, a buried region formed by implantation may result in some implantation in the region between the buried region and the surface through which the implantation takes place.

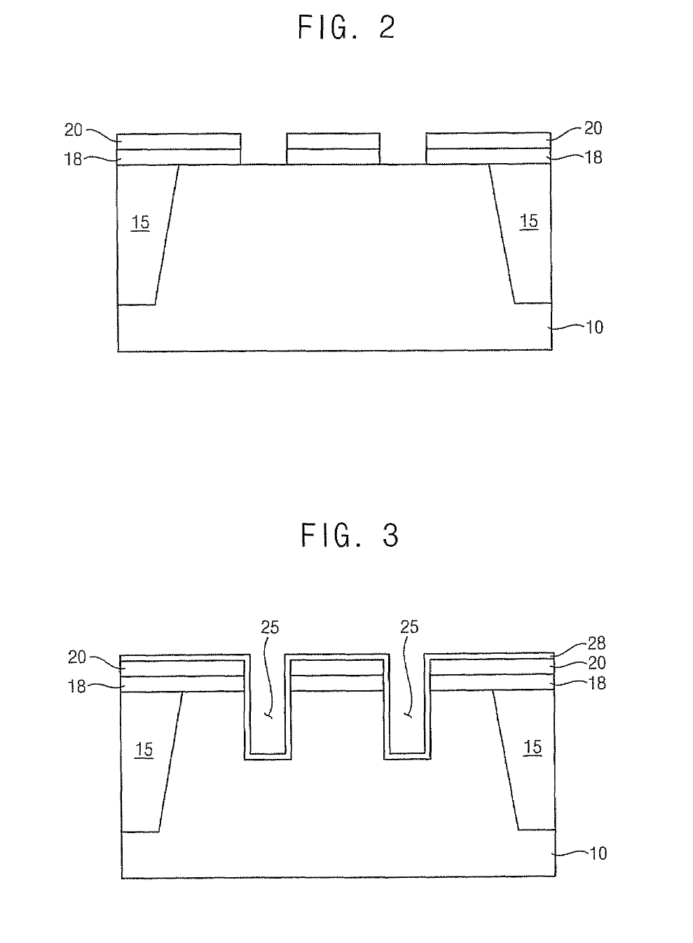

Reference is now made to FIG. 2, which is a cross-sectional view illustrating operations for forming an isolation layer 15, a pad oxide layer pattern 18 and a hard mask 20 on a substrate 10. An isolation layer 15 for defining an active region may be formed on the substrate 10. In some embodiments, the substrate 10 may include a semiconductor substrate including a silicon substrate, a germanium substrate, a silicon-germanium substrate, and/or a silicon-on-insulator (SOI) substrate, among others. In some embodiments, the isolation layer 15 may include an oxide such as silicon oxide. The isolation layer 15 may be formed by an isolation process, including, for example, a shallow trench isolation (STI) process and/or a thermal oxidation process, among others.

A pad oxide layer pattern 18 and a hard mask 20 may be formed on the substrate 10 having the isolation layer 15 The pad oxide layer 18 and hard mask 20 may expose a portion of the substrate 10 where a recess structure 40 (see FIG. 5) is formed.

In some embodiments, the pad oxide layer pattern 18 may be formed using an oxide such as, for example, silicon oxide. Some embodiments provide that the oxide layer pattern 18 may be formed using middle temperature oxide (MTO). The pad oxide layer pattern 18 may be formed by a chemical vapor deposition (CVD) process, a thermal oxidation process, a plasma-enhanced chemical vapor deposition (PECVD) process, an atomic layer deposition (ALD) process, a low-pressure chemical vapor deposition (LPCVD) process, and/or a high-density plasma chemical vapor deposition (HDP-CVD) process, among others.

In some embodiments, the hard mask 20 may be formed using a material having an etching selectivity with respect to the substrate 10 and the pad oxide layer pattern 18. For example, the hard mask 20 may be formed using a nitride such as silicon nitride and/or an oxynitride such as silicon oxynitride, among others. The hard mask 20 may be formed by a CVD process, a PECVD process, an ALD process, an LPCVD process, and/or a sputtering process, among others.

In some embodiments, the pad oxide layer pattern 18 and the hard mask 20 may be formed on the substrate 10 by a photolithography process. For example, after a pad oxide layer and a hard mask layer are successively formed on the substrate 10, the photolithography process may be performed on the pad oxide layer and the hard mask layer to form the pad oxide layer pattern 18 and the hard mask 20 on the substrate 10. Thus, the portion of the substrate 10 for the recess structure 40 may be exposed by the pad oxide layer pattern 18 and the hard mask 20. According to some embodiments of the present invention, as the degree of integration of the semiconductor device increases, the photolithography process may be preformed on the hard mask layer to form the hard mask 20 after the hard mask layer that may include nitride and/or oxynitride is formed on the substrate 10. In some embodiments, when the semiconductor device has a relatively large design rule, a photoresist pattern formed on the substrate 10 by a photolithography process may serve as an etching mask for forming the recess structure 40.

Reference is now made to FIG. 3, which is a cross-sectional view illustrating operations for forming a first preliminary recess 25 and an insulation layer 28 on the substrate 10. A first etching process may be performed on the portion of the substrate 10 using the hard mask 20 and/or the pad oxide layer pattern 18 as etching masks. Thus, the first preliminary recess 25 may be formed at an upper portion of the substrate 10. In some embodiments, the portion of the substrate 10 exposed by the hard mask 20 and the pad oxide layer pattern 18 may be etched to form the first preliminary recess 25 along a direction substantially perpendicular to the substrate 10. The first preliminary recess 25 may have a first width and a first depth measured from an upper face of the substrate 10.

In some embodiments, the first etching process may include an isotropic etching process. In some embodiments of the isotropic etching process, ingredients of an etching gas for etching the substrate 10 may be adjusted to form the first preliminary recess 25 having the first width and the first depth along a direction substantially vertical with respect to the substrate 10. In some embodiments, the first etching process may include a wet etching process and/or a dry etching process.

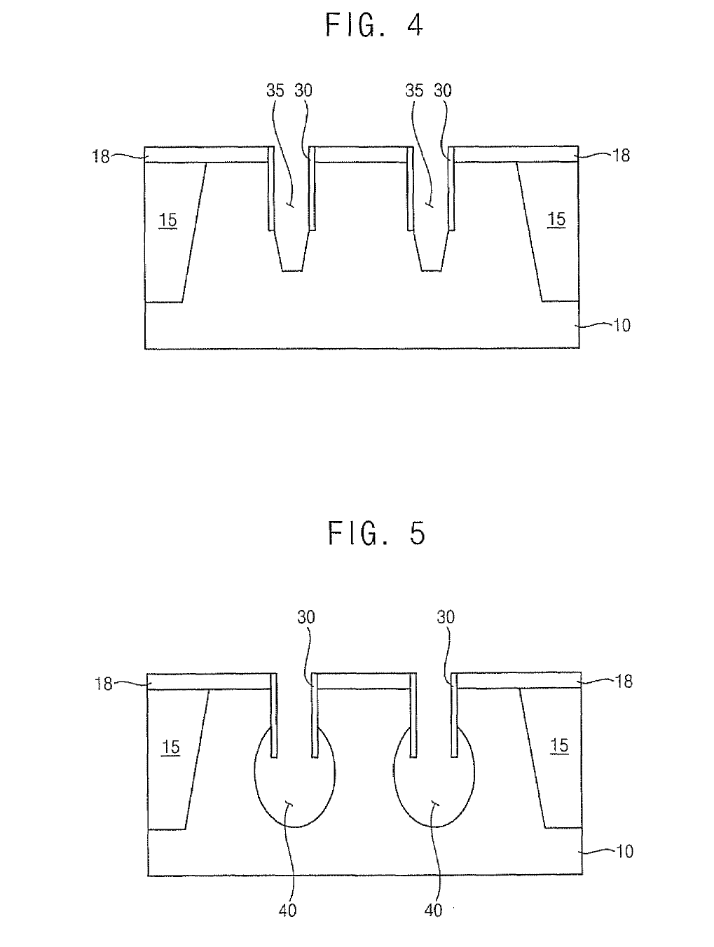

The insulation layer 28 for forming a spacer 30 (see FIG. 4) may be continuously formed on a bottom face and a sidewall of the first preliminary recess 25 and/or on the hard mask 20. The insulation layer 28 may be formed using a material having an etching selectivity relative to the substrate 10. For example, the insulation layer 28 may be formed using a nitride such as silicon nitride and/or an oxynitride such as, for example, silicon oxynitride. In some embodiments, the insulation layer 28 may be formed by a CVD process, a PECVD process, an ALD process, and/or an LPCVD process, among others. In some embodiments, the insulation layer 28 may be formed using a material substantially the same as that of the hard mask 20. In some embodiments, the insulation layer 28 may be formed using a material different from that of the hard mask 20.

Reference is now made to FIG. 4, which is a cross-sectional view illustrating operations for forming a spacer 30 and a second preliminary recess 35. The insulation layer 28 may be etched by an anisotropic etching process to form the spacer 30 on a sidewall of the first preliminary recess 25. In some embodiments, the insulation layer 28 may include a material substantially the same as that of the hard mask 20. The insulation layer 28 formed on the hard mask 20 and the first preliminary recess 25 may be removed in the anisotropic etching process. Simultaneously, the hard mask 20 formed on the pad oxide layer pattern 18 may also be removed. In some embodiments, the spacer 30 may be formed using an etching solution and/or an etching gas including phosphoric acid, among others, when both of the insulation layer 28 and the hard mask 20 include silicon nitride.

When the spacer 30 is formed on the sidewall of the first preliminary recess 25, a portion of the substrate 10 corresponding to a bottom face of the first preliminary recess 25 may be exposed. Since the spacer 30 may include the material having an etching selectivity relative to the substrate 10, an end point of the etching process for forming the spacer 30 may be precisely controlled. Further, an area of the exposed portion of the substrate 10 (corresponding to the bottom face of the first preliminary recess 25) may be adjusted by properly controlling a processing time of the etching process.

In some embodiments, a thickness of the spacer 30 may be adjusted to a desired value by considering an amount of the substrate 10 to be etched in a subsequent etching process for forming the recess structure 40. For example, in some embodiments, the spacer 30 may have a thickness of about 100 Å to about 200 Å measured from the sidewall of the first preliminary recess 25. In some embodiments, the spacer 30 may have a thickness of about 150 Å measured from the sidewall of the first preliminary recess 25. Some embodiments provide that the spacer 30 may have a single-layer structure that includes a nitride layer or an oxynitride layer. In some embodiments, the spacer 30 may have a multilayer structure that includes a nitride layer and an oxynitride layer.

A second etching process may be performed on the substrate 10 using the spacer 30 as an etching mask to form a second preliminary recess 35 from the first preliminary recess 25. In some embodiments, a portion of the substrate 10 exposed by the first preliminary recess 25 may be partially etched to form the second preliminary recess 35 having a second width and a second depth along a direction substantially perpendicular to the upper face of the substrate 10. In some embodiments, the second width of the second preliminary width 35 may be substantially the same as the first width of the first preliminary width 25 and the second depth of the second preliminary recess 35 may be greater than the first depth of the first preliminary recess 25.

The second depth of the second preliminary recess 35 may be a factor for determining a channel length of the semiconductor device. Accordingly, the second depth may vary in accordance with desired electrical characteristics of the semiconductor. Further, since a relationship between the second depth of the second preliminary recess 35 and a width of the substrate 10 between the second preliminary recess 35 and the isolation layer 15 may be a variable for determining processing conditions, such as, for example, a processing time for forming the recess structure 40, the second width and the second depth of the second preliminary recess 35 may be adjusted to desired values, respectively.

In some embodiments, the second etching process for forming the second preliminary recess 35 may include an isotropic etching process. For example, the substrate 10 exposed through the bottom face of the first preliminary recess 25 may be partially etched by the anisotropic etching process to form the second preliminary recess 35 having the second depth greater than the first depth of the first preliminary recess 25. In some embodiments, the second etching process may include a wet etching process and/or a dry etching process substantially similar to those of the first etching process.

Reference is now made to FIG. 5, which is a cross-sectional view illustrating operations for forming the recess structure 40 on the substrate 10. A third etching process may be performed on the substrate 10 still using the spacer 30 as an etching mask to form the recess structure 40 from the second preliminary recess 35. That is, a lower portion of the second preliminary recess 35 below the spacer 30 may be enlarged to form the recess structure 40. In some embodiments, the recess structure 40 may have a third width relatively larger than the second width of the second preliminary recess 35. Some embodiments may provide that the recess structure 40 may have a third depth relatively greater than the second depth of the second preliminary recess 35. In some embodiments, the third etching process may include an isotropic etching process. In some embodiments, the third etching process may include a wet etching process and/or a dry etching process.

According to some embodiments of the present invention, the lower portion of the second preliminary recess 35 may be enlarged into a circular and/or elliptical shape by the isotropic etching process to provide the recess structure 40 at the upper portion of the substrate 10. The recess structure 40 having the enlarged lower portion may be formed by a dry etching process and/or a wet etching process. In some embodiments, the recess structure 40 may be formed by a wet etching process only in order to improve electrical characteristics of a gate insulation layer 50 (see FIG. 7). Since the electrical characteristics of the gate insulation layer 50 may depend on a surface of the recess structure 40 provided on the substrate 10, the electrical characteristics of the gate insulation layer 50 may be factors for determining electrical characteristics of the semiconductor device. Accordingly, the recess structure 40 may be formed by the wet etching process in order to provide desired surface conditions of the recess structure 40.

In the third etching process for forming the recess structure 40, the third etching process may be carried out until the lower portion of the spacer 30 is exposed. Because the substrate 10 may be partially etched to form the recess structure 40 having a minute size, the substrate 10 may be etched using an etching solution suitable for controlling an end point of the etching process. When the etching solution having a high etching selectivity with respect to the substrate 10 is used, the substrate 10 may be etched for a short time, which may generate a cusp (that is, a sharp protrusion) between the upper portion and the lower portion of the recess structure 40. In this regard, an etching solution having a low etching selectivity relative to the substrate 10 may be used for forming the recess structure 40 without formation of a cusp. Further, as described with reference to FIG. 4, the end point of the etching process may be accurately detected by considering the second depth of the second preliminary recess 35 and the width of the substrate 10 between the second preliminary recess 35 and the isolation layer 15. In this manner, the recess structure 40 may be formed having a gentle curvature (that is, a relatively large inclination angle) between the upper and lower portions thereof. Accordingly, the recess structure 40 may be formed by considering the second depth of the second preliminary recess 35 and the width of the substrate 10 between the second preliminary recess 35 and the isolation layer 15.

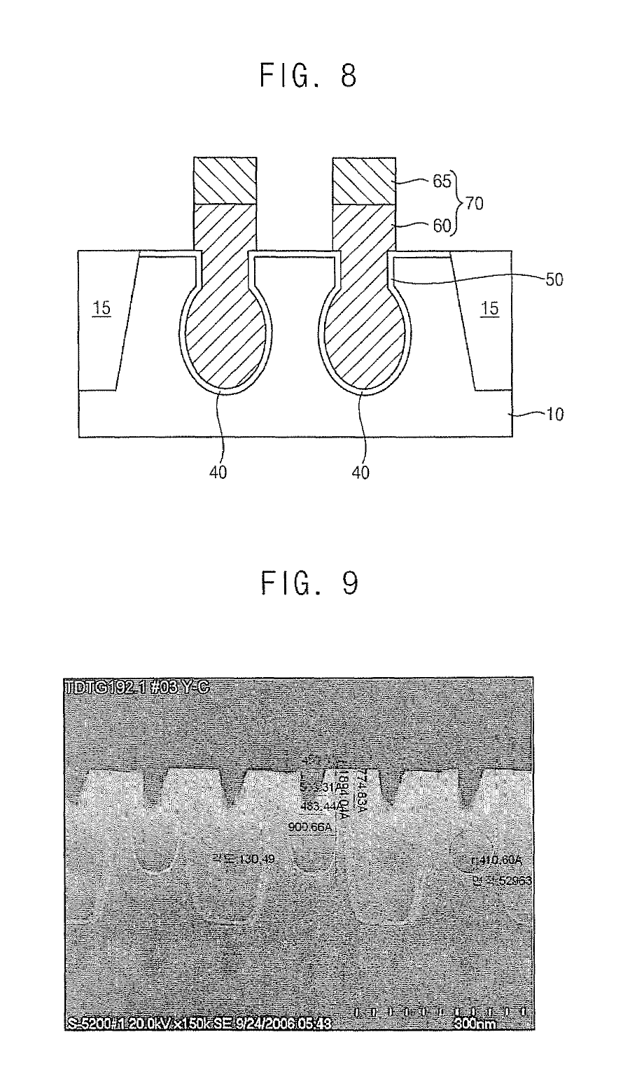

The etching process for forming the recess structure 40 may be preformed until the lower portion of the spacer 30 is sufficiently exposed through the lower portion of the recess structure 40. In this regard, the inclination angle between the upper portion and the lower portion of the recess structure 40, which is positioned at a middle portion of the spacer 30, may be properly adjusted. When the inclination angle between the upper portion and the lower portion of the recess structure 40 is greater than about 130°, the gate insulation layer 50 and a gate structure 60 (see FIG. 8) may be formed in the recess structure 40. To provide the inclination angle of greater than about 130° between the upper portion and the lower portion of the recess structure 40, an inclination of the sidewall of the second preliminary recess 35 may be steep and the upper portion of the recess structure 40 may be slightly etched in a direction substantially in parallel to the substrate 10 in the etching process for forming the recess structure 40. In some embodiments, the channel length along a circumferential portion of the recess structure 40 may be reduced when the upper portion of the recess structure 40 is slightly etched and the lower portion of the recess structure 40 may be enlarged into the circular or elliptical shape. Accordingly, the processing time and the etching solution may be properly controlled in the etching process for forming the recess structure 40.

In some embodiments, the pad oxide layer pattern 18 may be partially removed during the third etching process for forming the recess structure 40 when the pad oxide layer pattern 18 includes oxide.

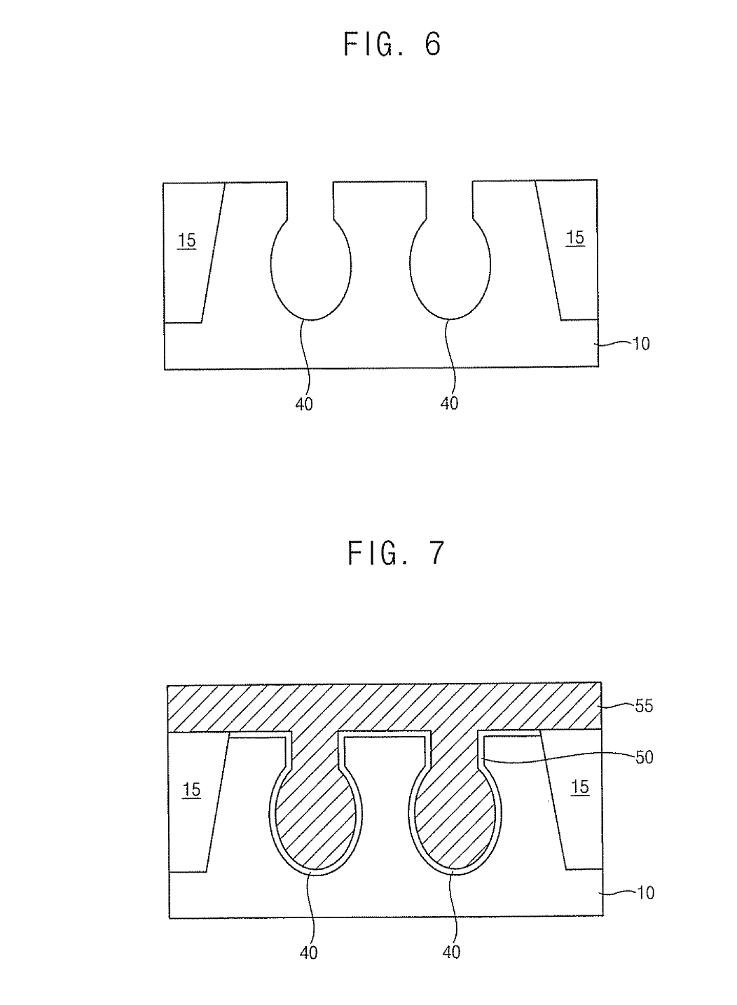

Reference is now made to FIG. 6, which is a cross-sectional view illustrating operations for removing the spacer 30 to complete the recess structure 40. After the recess structure 40 is formed on the substrate 10, the spacer 30 may be removed from the recess structure 40 to complete the recess structure 40 in the active region of the substrate 10. In some embodiments, the spacer 30 may be removed from the substrate 10 using an etching solution and/or an etching gas including phosphoric acid when the spacer 30 includes nitride.

In some embodiments, after the spacer 30 is removed from the substrate 10, a wet etching process may be performed to remove undesirable materials remaining in the recess structure 40. Then, the pad oxide layer pattern 18 including oxide may be completely removed from the substrate 10. In the cleaning process, the cleaning solution having a low etching selectivity relative to the substrate 10 may be used to remove a small cusp formed between the upper and the lower portions of the recess structure 40.

Reference is now made to FIG. 9, which is an electron microscope image illustrating a cross-section of a recess structure formed on the substrate according to some embodiments of the present invention. As illustrated in FIGS. 6 and 9, the recess structure 40 on the substrate 10 includes the gentle curvature between the upper and lower portions thereof. That is, the recess structure 40 includes a gentle curvature (the inclination angle of more than about 130°) and thus a cusp between the upper portion and the lower portion of the recess structure 40 may not be generated. Since the recess structure 40 may have a rounded surface, the gate insulation layer 50 formed on the rounded surface of the recess structure 40 may have a sufficiently uniform thickness substantially the same as that of other portions of the gate insulation layer 50. When a recessed-gate structure 70 (see FIG. 8) is formed in the recess structure 40, a stress generated in the recessed-gate structure 70 may be effectively dispersed and thereby reduce defects of the recessed-gate structure 70. Further, since the recess structure 40 may have the gentle curvature of about more than 130° between the upper portion and the lower portion, a first conductive layer 55 (see FIG. 7) may be filled up in the recess structure 40 to reduce the generation of voids at a lower portion of a first conductive layer pattern 60 (see FIG. 8). Mien the recess structure 40 having the gentle curvature between the upper portion and the lower portion is filled with the recessed-gate structure 70, the electrical characteristics and reliability of the semiconductor device may be improved. The gate insulation layer 50 and the recessed-gate structure 70 may be formed in the recess structure 40 having a large inclination angle between the upper portion and lower portion, so that defects of the gate insulation layer 50 due to the cusp of a recess structure may be reduced and/or prevented. Accordingly, an occurrence of failure of a word line including the recessed-gate structure 70 may be reduced.

Reference is now made to FIG. 7, which is a cross-sectional view illustrating operations for forming the gate insulation layer 50 and the first conductive layer 55. The gate insulation layer 50 may be formed on the inner portion of the recess structure 40 and the active region of the substrate 10. In some embodiments, the gate insulation layer 50 may be formed using an oxide or a high-k (a high dielectric constant) metal oxide. Some embodiments provide that the gate insulation layer 50 may be formed using silicon oxide, titanium oxide (TiOx), zirconium oxide (ZrOx), and/or hafnium oxide (HfOx), among others. The gate insulation layer 50 may be formed by a thermal oxidation process, a CVD process, and/or an ALD process, among others. In some embodiments, the gate insulation layer 50 may have a thickness of about 50 Å to about 100 Å from the inner portion of the recess structure 40.

The first conductive layer 55 may be formed on the gate insulation layer 50 to sufficiently fill up the recess structure 40. The first conductive layer 55 may be formed using a conductive material such as doped polysilicon, metal, and/or conductive metal nitride, among others. The first conductive layer 55 may be formed by an LPCVD process, a CVD process, a sputtering process, a PECVD process, a pulsed laser deposition (PLD) process, and/or an ALD process, among others. If the first conductive layer 55 includes doped polysilicon, a polysilicon layer may be formed on the gate insulation layer and then impurities may be doped into the polysilicon layer to form the first conductive layer 55 by a diffusion process, an ion implantation process, and/or an in-situ doping process, among others.

Reference is now made to FIG. 8, which is a cross-sectional view illustrating operations for forming the recessed-gate structure 70. After a second conductive layer (not illustrated) is formed on the first conductive layer 55, the second conductive layer and the first conductive layer 55 may be successively patterned to form the recessed-gate structure 70 including the first conductive layer pattern 60 and a second conductive layer pattern 65. In some embodiments, the second conductive layer may be formed using metal silicide or metal. In some embodiments, the second conductive layer may have a multilayer structure that includes a metal silicide film and a metal film. In some embodiments, the second conductive layer may be formed using tungsten silicide (WSix), titanium silicide (TiSix), cobalt silicide (CoSix), tungsten (W), titanium (Ti) and/or cobalt (Co), among others.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A method of forming a recess structure, comprising:
forming a hard mask on a substrate;
forming a first preliminary recess on the substrate using the hard mask as an etching mask;
forming a spacer on a sidewall of the first preliminary recess;
forming a second preliminary recess from the first preliminary recess using the spacer as an etching mask; and
forming the recess structure having an enlarged lower portion from the second preliminary recess using the spacer as an etching mask.

2. The method of claim 1, further comprising forming a pad oxide layer pattern between the substrate and the hard mask.

3. The method of claim 2, wherein forming the pad oxide layer pattern and forming the hard mask comprise:
forming a pad oxide layer on the substrate;
forming a hard mask layer on the pad oxide layer; and
partially etching the hard mask layer and the pad oxide layer.

4. The method of claim 2, wherein forming the pad oxide layer pattern comprises using oxide and forming the hard mask comprises using nitride and/or oxynitride.

5. The method of claim 1, wherein the first preliminary recess includes a first width and a first depth and wherein the second preliminary recess includes a second width that is substantially the same as the first width and a second depth that is substantially greater than the first depth.

6. The method of claim 1, wherein forming the first preliminary recess comprises performing an anisotropic etching process.

7. The method of claim 1, wherein forming the second preliminary recess comprises performing an anisotropic etching process.

8. The method of claim 1, wherein forming the recess structure comprises performing an isotropic etching process.

9. The method of claim 8, wherein forming the second preliminary recess comprises etching until a lower portion of the spacer is exposed.

10. The method of claim 1, wherein an inclination angle between an upper portion and the lower portion of the recess structure is greater than about 130°.

11. The method of claim 10, wherein the lower portion of the recess structure comprises a circular shape.

12. The method of claim 1, further comprising cleaning the recess structure.

13. The method of claim 1, further comprising removing the hard mask while forming the spacer.

14. A method of manufacturing a semiconductor device, comprising;
forming an isolation layer on a substrate to define an active region;
forming a hard mask on the substrate;
forming a first preliminary recess in the active region of the substrate using the hard mask as an etching mask;
forming a spacer on a sidewall of the first preliminary recess;
forming a second preliminary recess from the first preliminary recess using the spacer as an etching mask;
forming a recess structure having an enlarged lower portion from the second preliminary recess using the spacer as an etching mask;
forming a gate insulation layer on an inner portion of the recess structure and the substrate; and
forming a recessed-gate structure having a lower portion filling the recess structure on the gate insulation layer.

15. The method of claim 14, wherein forming the recess structure comprises etching the second preliminary recess until a lower portion of the spacer is exposed.

16. The method of claim 14, wherein a lower portion of the recess structure comprises an elliptical shape and wherein an inclination angle between an upper portion and the lower portion of the recess structure is greater than about 1300.

17. The method of claim 14, further comprising removing the hard mask while forming the spacer.

18. The method of claim 14, wherein the gate insulation layer comprises silicon oxide or a metal oxide having a high dielectric constant.

19. The method of claim 14, wherein forming the recessed-gate structure further comprises:
forming a first conductive layer pattern that is configured to fill the recess structure and protrude from the substrate; and
forming a second conductive layer pattern on the first conductive layer pattern.

20. A method of manufacturing a semiconductor device, comprising:
forming an isolation layer on a substrate to define an active region;
forming a hard mask on the substrate;
forming a first preliminary recess in the active region of the substrate using the hard mask as an etching mask;
forming a spacer on a sidewall of the first preliminary recess;
forming a second preliminary recess from the first preliminary recess using the spacer as an etching mask;
forming a recess structure having an enlarged lower portion from the second preliminary recess using the spacer as an etching mask;
cleaning the substrate that includes the recess structure to remove a cusp formed between the first preliminary recess and the second preliminary recess;
forming a gate insulation layer on an inner portion of the recess structure and the substrate; and
forming a recessed-gate structure having a lower portion filling the recess structure on the gate insulation layer.
